(19) United States
(12) Patent Application Publication
(10) Pub. No.: US 2026/0231563 A1
(43) Pub. Date: Aug. 6, 2026

(54) OPTOELECTRONIC DEVICE AND METHOD FOR PROCESSING THE SAME

(71) Applicant: ams-OSRAM International GmbH, Regensburg (DE)

(72) Inventors: Tansen Varghese, Regensburg (DE); Adrian Avramescu, Regensburg (DE); Marta Rio Calvo, Regensburg (DE)

(21) Appl. No.: 19/149,742

(22) PCT Filed: Jan. 18, 2024
(86) PCT No.: PCT/EP2024/051195

§ 371 Date: Jul. 21, 2025

(30) Foreign Application Priority Data
Jan. 23, 2023 (DE) 10 2023 101 572.9

(51) Int. Cl. H10H 20/816; H10H 20/01; H10H 20/824

(52) U.S. Cl. CPC H10H 20/816; H10H 20/0133; H10H 20/017; H10H 20/8242

(57) ABSTRACT

In an embodiment an optoelectronic device includes a layer stack having a first charge carrier transportation layer of a first doping type, a second charge carrier transportation layer of a second doping type, and an active region arranged between the first and second charge carrier transportation layers, wherein the layer stack has a top surface and side wall surfaces adjacent to the top surface, and wherein the side wall surfaces are inclined with respect to a normal of the top surface, a first regrowth layer covering the side wall surfaces and leaving at least portions of the top surface exposed, wherein the first regrowth layer includes a larger bandgap than at least the active region and is undoped or includes a plurality of sub-layers of a different doping type arranged in an alternating order and a second regrowth layer arranged on exposed portions of the top surface thereby forming a p-doped contact layer to the second charge carrier transportation layer, and a structured insulating material covering portions of the top surface and extending on surface portions of the first regrowth layer substantially on the same level as the top surface.

### CROSS-REFERENCE TO RELATED APPLICATIONS

This patent application is a national phase filing under section 371 of PCT/EP 2024/051195, filed Jan. 18, 2024, which claims the priority of German patent application no. 10 2023 101 572.9, filed Jan. 23, 2023, each of which is incorporated herein by reference in its entirety.

### TECHNICAL FIELD

The present invention concerns an optoelectronic device with 2-stage regrowth approach to increase the quantum efficiency of the optoelectronic device, as well as a method for processing the optoelectronic device.

### BACKGROUND

Mesa etching of optoelectronic devices, in particular μ-LEDs, is done to optically and electrically isolate the individual devices on a wafer. This technique can be applied to all sizes for optoelectronic devices during the processing process but is usually done when producing μ-LEDs having length in the range of 20 μm and even below down to less than 5 μm. The mesa etching however causes non-radiative recombination (NRR) of charge carriers at the mesa edges, due to resulting defects (dangling bonds which act as non-radiative recombination centres) in the structure of the optoelectronic device along the mesa edges. Current spreading in the layers above and below the active region and also through the active region allows charge carriers to propagate in the direction of the pixel edges, which may then recombine non-radiatively at the defects, lowering the quantum efficiency of the optoelectronic device.

This effect is of lesser relevance for optoelectronic device based on nitride material systems due to the short diffusion length of charge carriers in this material system. However, for materials based on phosphide like in InGaP, InAlP or Indium Gallium Aluminium Phosphite (InGaAlP)-based μ-LEDs, the diffusion length is significantly larger and may even be larger than the length of those devices. μ-LEDs based on such material systems are usually used for red colour to yellow colour emission, although the emission wavelength can be varied with composition.

So far different methods have been employed to counteract the aforementioned problem depending on the material system used for the optoelectronic devices, one of it being a passivation of the mesa edges. Particularly for the InGaAlP material system, which is usually used for yellow/red emission, two main methods in order to reduce NRR at the mesa facet have been employed: quantum well intermixing (QWI) & regrowth.

In QWI, intentional diffusion of impurities or vacancies (impurity-free QWI) leads to an intermixing of the QWs in the active region with the adjacent high-bandgap barriers, leading to an overall increase of the local bandgap. When applied at the pixel edges, this results in a lateral electric barrier for charge carriers to prevent diffusion from the inner area to the outer area of the active region. However, QWI has technological limitations, in particular when reducing the pixel sizes in particular down to the length of the above mentioned μ-LEDs.

### SUMMARY

Embodiments provide an optoelectronic device, in particular a small optoelectronic device such as a μ-LED, with an increased quantum efficiency. Further embodiments provide a method for processing an optoelectronic device, in particular a small optoelectronic device such as a μ-LED, with an increased quantum efficiency.

For very small optoelectronic devices, a multi-step epitaxy approach has been proposed although referred to as regrowth approach.

An epi structure including an active region is grown on a wafer in a first step. Then, the wafer surface is pre-structured (referred to as mesa etching) to isolate individual islands of the active region which each form an optoelectronic device later on, or form pixels or an array of individually addressable devices. The regrowth approach is done by applying a high-bandgap material on the same wafer in order to encapsulate the outstanding islands with their active regions, and in particular the mesa edges of the active region. In subsequent etching step (second mesa etching) and with additional processing such as applying mirror layers, the optoelectronic device or pixel is then optically and electrically isolated outside the passivated “active region islands” of the optoelectronic devices.

In this way, a potential barrier in between the core of the respective device and the mesa facet appears, blocking charge carriers from diffusing to the side surfaces. The regrowth process can also include steps for applying passivation layers based on ALD (atomic layer deposition) based on, for example, Al2O₃ material. Those materials reduce the non-radiative recombination at the side facets. Pre-passivating etches and cleaning methods to remove, e.g. native oxides and defects, have also been employed in order to reduce the non-radiative recombination. While such methods can work for different material systems, the results thereof usually tend to deteriorate at decreasing sizes of the optoelectronic device. Particularly, for the production of highly efficient μ-LEDs with pixel sizes <5 μm, some of the applied techniques have proven to provide insufficient results.

Some aspects concern a method for processing an optoelectronic device. In a first step a layer layer stack is provided. The layer stack comprises a first a first charge carrier transportation layer of a first doping type, a second charge carrier transportation layer of a second doping type, and an active region arranged between the first and the second charge carrier transportation layer. The layer stack is epitaxially grown, and each transportation layer may comprise a plurality of sublayers having different functionality or serving different purposes. In some instances, sublayers directly adjacent to the active region are grown without any dopant, that is they are undoped.

A structured mask is provided on a top surface of the layer stack, and the layer stack is subsequently etched, thereby exposing edges of the active region. The sidewalls can be inclined with the top surface having the smallest area. A first regrowth layer is regrown at least on the side wall surfaces, wherein the first regrowth layer is undoped or comprises a plurality of sub-layers of different doping types arranged in an alternating order. Portions of the top surface of the layer stack are exposed and a second regrowth layer is regrown on at least the exposed portions of the top surface, wherein the second regrowth layer comprises one or more sub-layers, the outermost sub-layer forming a doped contact layer.

In some further instances, the step of etching the layer stack comprises etching below the bottom surface of the structured mask to form an undercut thereof. In other words, the structured mask will rest on the top surface extending beyond the edges of the inclined surfaces.

In some further instance, the step of regrowing a first regrowth layer comprises regrowing an undoped layer of a ternary or quaternary semiconductor material having an Al content that is larger than the Al content of the active region and/or the first and second charge carrier transportation layers. The increased Al content will increase the bandgap thereby creating the electrical barrier.

In some further instances, the step of regrowing a first regrowth layer comprises regrowing one or more doped layers on top of the undoped layers such, that a pnpn or npnp structure is formed with the undoped layer in between one of the pn- or np-junctions and in which one of the p or n layers is part of the first and/or second charge carrier transportation layer, respectively. In other words, the first regrowth layer may comprise one or more doped sub-layers, which when stacked on each other form a thyristor-like structure with regards to the first and second charge carrier transportation layer or sub-layers thereof. As a result, an electrical barrier is created preventing current leakage through the regrown layers.

In some further instances, the second regrowth layer may comprise sublayers with the same or similar material composition as the second charge carrier transportation layer. For example, the material composition may include InAlP or InGaAlP or InGaP. In some aspects, an InAlP layer is deposited on at least exposed portions of the top surface, and an InGaAlP sub-layer is deposited thereupon thereafter. In some further instances, the second regrowth layer comprises a p-doped GaP layer as the topmost sublayer. This sublayer also acts as contact and can for example be connected to a metal or ITO for electrical contact to the optoelectronic device.

Some further aspects concern different implementation of optimizing the first and second regrowth layers separately. In some instances, the structured mask is removed to form a substantially flat surface between the top surface and the upper edges of the first regrowth layer. In such cases, the second regrowth layer may be deposited on the exposed top surface.

In some other aspects, the mask material is left on the device. In such implementations, the step of regrowing a second regrowth layer comprises forming a recess in the structured mask to expose a portion of the top surface, wherein optionally the recess is formed substantially centrally on the top surface distanced towards material of the first regrowth layer. The second regrowth layer is regrown in said recess. Apart from the insulating effect of the mask material, it also provides the benefit of omitting another re-alignment step. Rather the mask layer is simply be restructured.

Some other aspects concern regrowing a first regrowth layer. For example, it may comprise removing the structured mask layer and then regrowing the first regrowth layer on sidewall surfaces and the top surface. In such an implementation the first regrowth layer also temporarily covers the top surface during processing of the device.

Then, the second regrowth layer may be regrown thereupon, by first providing a mask layer on top the first regrowth layer. The mask layer is structured to form a recess through the structured mask and the material of the first regrowth layer to expose a portion of the top surface. The sidewalls of such recess may be inclined or perpendicular to the exposed surface.

Again, a previous alignment is performed such that the recess is mainly located centrally on the layer stack's top surface. In some aspects, the sidewalls of first regrowth layer portion in said recess are covered by an insulating layer to prevent current leakage. Then, the second regrowth layer in the recess. The optional insulation layer will prevent a current leakage from the second regrowth layer into the first regrowth layer. However, the insulating layer can be omitted if the area resistance of the first regrowth layer is relatively high, and any current leakage is negligible.

In some instances, the step of structuring the layer stack comprises a step of etching the layer stack such that the structured mask protrudes over the side wall surfaces of the layer stack.

The present application therefore proposes to perform the regrowth process in two separates steps, which can be optimized independently from each other. The regrowth comprises a first regrowth process that selectively regrow blocking layers around the active region on the side faces created by a mesa etching process. The hard mask used for etching is also used a selective growth mask. This will simplify the process, and also reduce alignment issues. The blocking layers can be undoped or semi-insulating, for example Fe-doped. In addition, some or more p- or n-doped like layers can be applied to create a pnpn blocking structure similar to that of a thyristor.

In some instances, the application of the second regrowth layer is facilitated differently. For example, the selective growth mask is etched away prior to regrowing the second regrowth doped layer including the contact layer. Regrowing the second regrowth layer may also comprise one or more p-barrier (or n-, if reversed) layers. Alternatively, the etchant mask and in some instances, the first regrowth also can be selectively etched to expose the charge carrier transportation layer. The second regrowth layer is then regrown to fill the gap in the mask. The mask material can be left in such implementation on the device and form an integral part thereof. Other implementations using a further structured mask layer are also possible.

With these methods, the top layers and the blocking layers can be independently optimized for material composition, thickness and doping level. By choosing an undoped first blocking layer, dopant diffusion into the active region can be minimized, for example. And the blocking action prevents leakage current around the core and forces all the current to go through the core and contribute to light emission. This will increase the overall quantum efficiency.

The inventors also propose an optoelectronic device, that is implemented particularly as a μ-LED with a side length of less than 20 μm and down to a few μm. The optoelectronic device comprises a layer stack having a first charge carrier transportation layer of a first doping type, a second charge carrier transportation layer of a second doping type, and an active region arranged between the first and the second charge carrier transportation layer. The first doping type can be for example of n-type, the second doping type is of a p-doping type.

In some instances, the respective charge carrier transportation layer may comprise different sub-layers, being undoped or having at least different doping concentrations. This may improve the current distribution towards the active region. In some instances, the first and/or second transportation layer may comprise an undoped cladding layer adjacent to the active region. The undoped cladding layer acts as a diffusion barrier to prevent dopant from the n- or p-doped layers to diffuse into the active region. The cladding layer may comprise a thickness of a few nm up to a few 10 nm. The material of the cladding layers may be the same as the doped layers adjacent to the cladding layers, but undoped for the reasons mentioned above.

The layer stack of the optoelectronic device comprises a top surface as well as side surfaces adjacent to the top surface, and wherein the side surfaces are inclined with respect to a normal of the top surface. The inclined side surfaces are formed by a mesa etching process. The inclination is such, that the top surface layer comprises an area smaller than areas in parallel planes towards the direction of the first charge carrier transportation layer.

In accordance with the proposed principle, the optoelectronic device further comprises a first regrowth layer covering the side surfaces and leaving at least portions of the top surface exposed. The first regrowth layer comprises a larger bandgap than at least the active region.

Depending on the implementation, the first regrowth layer may be undoped. An undoped layer prevents diffusion of dopants into the active region, which will reduce defects at the edges of the active region and improve quantum efficiency. Alternatively, the first regrowth can comprise a plurality of sub-layers, some of which may be doped, particularly with different doping types arranged in an alternating order. In some instances, the first regrowth layer may comprise a layer stack of undoped and/or differently doped sub-layers. Further details on the first regrowth layer are pointed out further below in this application.

The optoelectronic device in accordance with the proposed principle also comprises a second regrowth layer arranged on the exposed portions of the top surface thereby forming a p-doped contact layer, which is electrically contacted to the second charge carrier transportation layer. The two different blocking layers are independently optimized to prevent diffusion of dopants into the active region, but also provide the necessary electrical barrier.

In this regard it should be noted that the proposed principle is not limited to a certain order of n- or p-doped layers. The layer sequences illustrated herein are not limiting or restricting the proposed principle and can be reversed without departing from the given scope.

In some instances, the first regrowth layer of the optoelectronic device does not extend on the top surface but leaves the top surface exposed. This may for example achieved by a mask material covering the top surface during the regrowth. Hence, the second regrowth layer covers the top surface completely. In some instances, the second regrowth layer may also extend partially on exposed edges of the first regrowth layer. Those exposed edges of the first regrowth layer are substantially on the same level as the top surface.

In some further instances, the second regrowth layer extends on the first regrowth layer arranged on the side surfaces. The second regrowth layer is at least partially doped to provide a good contact to the second charge carrier transportation layer adjacent to the top surface.

Some aspects concern the implementation, form, and shape of the respective first and second regrowth layers. In some aspects, the optoelectronic device further comprises a structured insulating material covering portions of the top surface. The insulating material may also extend on surface portions of the first regrowth layer, which are substantially on the same level as the top surface. In other words, the insulating material covers the top edge portions of the first regrowth layer and the top surface, whereas a cavity is formed in the insulating material exposing portions of the top surface.

In some instances, the structured insulating material comprises a hard etch mask material. It is possible to re-use the hard mask used for the etching purpose as the regrowth layer is formed using a gas vapour or chemical vapor deposition process. Hence, in some aspects, the hard mask forming the insulating structured layer extends beyond the edges of the top surface. Such approach may reduce the processing steps simplifying the complexity in the processing of such devices. In addition, risks of misalignments are reduced, which is beneficial particularly for very small μLEDs.

If proper alignment can be achieved, the optoelectronic device further comprises in some other aspects a structured insulating material that extends on the first regrowth layer arranged on the side wall surfaces and on portions of the top surface. A cavity can be formed in the structured insulating material that extends through the structured insulating material and the first regrowth layer exposing portions of the top surface. The cavity is at least partially filled with the second regrowth layer. In some instances, the second regrowth layer can extend beyond the level of surface of the insulating material. Particularly, the second regrowth layer may comprise one or more sub-layers of which at least one sub-layer extends on the top surface of the insulating material. This will allow the forming of a good contact layer, while the insulating material may also act as a diffusion barrier for the p-dopants of the contact layer material of the second regrowth layer.

In some aspects, the second regrowth layer comprises at least three sub-layers. Those sub-layers can have the same material composition as sub-layers of the second charge carrier transportation layer. For example, some of the sub-layers of the second regrowth layer may be repeated in the same order as some sub-layers of the second charge carrier transportation layer when looking from the active region. Of course, doping levels may be different to reduce area and volume resistance and provide a good current insertion and/or spreading onto the second charge carrier transportation.

In some further aspects, the first and second charge carrier transportation layer each comprise a cladding layer, each of which is adjacent to the active layer. The cladding layers prevent dopant diffusion into the active layer. Their respective thickness may be in the range of a few nm to a few ten nm.

In some aspects, the first regrowth layer comprises a material with a larger Al content than the active region of the layer stack. In addition, the first regrowth layer may comprise a bandgap that is larger than the bandgap of the first and/or second transportation charge layer. The first regrowth layer may also comprise a bandgap that is larger than the bandgap second regrowth layer forming the contact layer.

In some aspects, the material composition of the first regrowth layer, the second regrowth layer and the active layer may follow the following equation (AlₓGa₁₋ₓ)_{y}In_{1-y}P, where x and y are in the range of [0:1]. The Al content for the first regrowth layer may be x>0.5.

Consequently, the first regrowth layer is based on a III-V semiconductor material, but it must not be constricted to the above mentioned InGaAlP material. Rather, the first regrowth layer can comprise in particular layers containing one of InP, AlP, GaP, InAlP, InGaP or InGaAIP material; and/or wherein the content of aluminium in the first regrowth layer is greater than 25%.

In some other aspects, the second regrowth layer comprises p-doped InGaAlP. Alternatively or in addition, the second regrowth layer may comprise the same material as the second charge carrier transportation layer. Furthermore in some aspects, the second regrowth layer may comprise a p-doped InAlP layer adjacent to the second charge carrier transportation layer upon which one of a p-doped InGaAlP and p-doped GaP contact layer is deposited.

The active layer may comprise a quantum well or a multi-quantum well structure. For instance, the active layer comprises a plurality of InGaAlP layers, whereas the Al content varies between barrier and recombination layers of the multi-quantum well structure. The thickness of the active region may vary but is usually in the range of a few 10 nm to about 200 nm.

In some instances, the first charge carrier transportation layer comprises a n-doped phosphide layer, like for example a InGaAlP followed by two undoped sub-layers arranged on the n-doped phosphide layer when viewed towards the active layer. In some instances, the doping as given above is reversed. The undoped sub-layer may comprise different material composition, with the undoped sub-layer adjacent to the active layer acting as cladding layer and comprising the same material system as the active region, although the concentration of the composition components, namely Al, Ga, or In may vary.

Likewise in some instances the second charge carrier transportation layer comprises an p-doped phosphide layer, like for example a p-doped InGaAlP followed by two undoped sub-layers arranged on the p-doped phosphide layer when viewed towards the active layer. In some instances, the doping as given above is reversed. The undoped sub-layer may comprise different material composition, with the undoped sub-layer adjacent to the active layer acting as cladding layer and comprising the same material system as the active region. However, the concentration of the composition components, namely Al, Ga, or In may vary with respect to the active layer.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows an optoelectronic device with resulting parasitic diodes;

FIG. 2 shows an optoelectronic device in accordance with a first aspect of the proposed principle;

FIG. 3A to 3D show some steps of a method for processing an optoelectronic device in accordance with some aspects of the proposed principle;

FIG. 4A to 4B illustrate the next steps of a method for processing an optoelectronic device in accordance with some aspects of the proposed principle;

FIG. 5A to 5B show some next steps of a method for processing an optoelectronic device in accordance with some aspects of the proposed principle; and

FIG. 6A to 6D illustrate some next steps of a method for processing an optoelectronic device in accordance with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

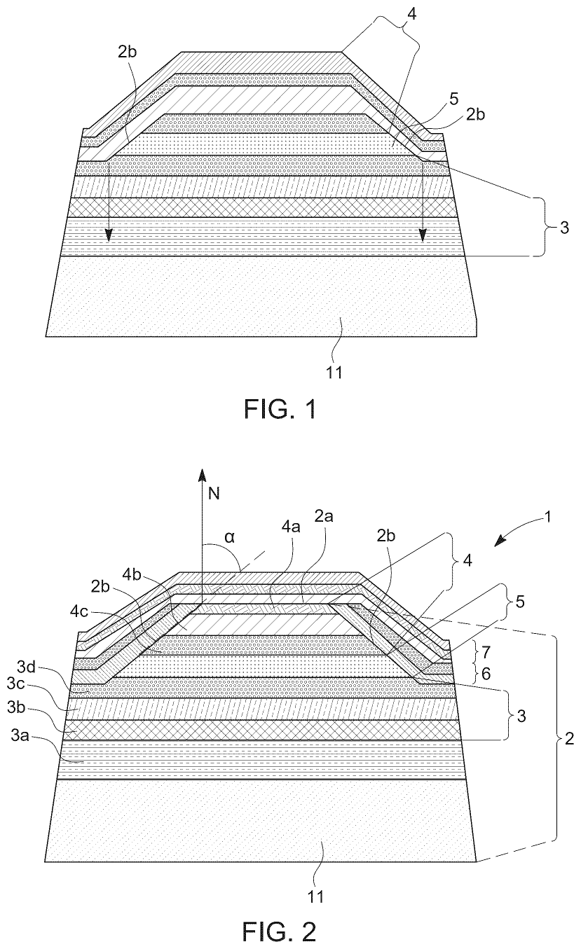

The problem with the regrowth process as described previously is that it necessitates doped layers to be regrown on top and around the active region and particularly on the exposed sidewall edges of the mesa structured device. This can have deleterious effects such as diffusion by the dopant of the regrowth layer into the active region. Such diffusion can degrade the active region by introducing new centres for non-radiative recombination. In addition, the first regrowth layer may also extend onto the n-doped charge carrier transportation layer, thereby creating an artificial yet undesired pn-junction. The pn-junction generates a parasitic current leakage through the diode formed by the regrown layers and the layers below and around the core, which can degrade light emission. FIG. 1 illustrates the issue.

FIG. 1 shows a cross section of an optoelectronic device with a reduced quantum efficiency due to parasitic diodes that form inside the optoelectronic device.

The optoelectronic device comprises an epitaxial layer stack including a first charge carrier transportation layer 3 on a buffer layer, an active region 5, as well as a first portion of a second charge carrier transportation layer 4, grown on a carrier substrate 11. The epitaxial layer stack is structured due to a mesa etching process resulting in the epitaxial layer stack having inclined side surfaces 2b. On the inclined side surfaces 2b of the epitaxial layer stack, a high-bandgap material, and in particular a second portion of the second charge carrier transportation layer 4 is regrown, in order to encapsulate the side surfaces 2b, and in particular the portions of the active region at the side surfaces 2b.

The optoelectronic device as a whole may then further be structured using a second mesa etching process to optically and electrically isolate several optoelectronic components from each other. In comparison to the previous mesa etching process the resulting side surfaces/mesa edges do not comprise portions of the active region.

In this way, an electrical barrier in between a central portion of the active of the optoelectronic device and the mesa edges thereof appears, blocking charge carriers from diffusing to the side surfaces. Furthermore, the risk of non-radiative recombination centres along the side surfaces 2b is usually reduced by the subsequent encapsulation of the etched side surfaces of the active region 5 with the regrowth material, which is subject to further etching process or can be covered by additional insulating layers. Hence, those further etching processes and other further handling does no longer or at least not significantly affect the side edges of at least the active region.

However, parasitic (nonradiative) diodes along the mesa edges besides the active region can lead to an intrinsic reduction of quantum efficiency of the optoelectronic devices. This parasitic diodes are exemplarily shown by use of the two vertical arrows to denote the leakage current next to the active region 5.

To counteract the aforementioned problem, the inventors propose an improved optoelectronic device with an increased quantum efficiency.

FIG. 2 shows an optoelectronic device 1 in accordance with some aspects of the proposed principle. The optoelectronic device 1 comprises a layer stack 2, in particular a semiconductor layer stack. The layer stack 2 comprises a first charge carrier transportation layer 3 of a first doping type, a second charge carrier transportation layer 4 of a second doping type, an active region 5 arranged between the first and the second charge carrier transportation layer, as well as a carrier substrate 11, on which the first charge carrier transportation layer 3 is arranged.

The layer stack 2 comprises a top surface 2a as well as inclined side surfaces 2b adjacent to the top surface, wherein the side surfaces are inclined with respect to a normal N of the top surface 2a with the angle a. The angle a can be based on the etching process as discussed below, but also depend on the crystal direction of the material used.

The angle can also vary along the sidewall with various angles being possible.

The first and the second charge carrier transportation layer 3 and 4, respectively can, as shown, each comprise several sub-layers, 3b, 3c, 3d and 4a, 4b as well as 4c to provide a layer stack together with the active region 5 configured to emit light of a desired wavelength when supplied with a sufficient current. Possible buffer layers like sublayer 3a in this embodiment may be removed and are not part of the current transport layer.

The first charge carrier transportation layer 3 can for example comprise one or several n-doped layers deposited on buffer layer 3a. Buffer layer 3a is adjacent to the carrier layer 11. Carrier layer 11 may comprise GaAs for example, on which a buffer layer of n-doped AlGaAs 3a of a charge carrier transportation layer 3 and subsequently the layers are deposited. This layer may later be removed.

On top of layer 3a several doped and/or undoped layers are provided acting as charge distribution layer, charge transportation layer or providing other and different functionalities. Layer 3d comprising InGaAIP for example is located directly adjacent to active region 5. This layer is undoped and may comprise only a thickness of a few 10 s of nm. It acts as a cladding layer to the active region and to prevent diffusion of dopants from layers 3a, 3b and 3c into the active region. A similar cladding layer 4c is provided on top of the active region, where cladding layer 4c forms a sub-layer of the second charge carrier transportation layer 4.

The second charge carrier transportation layer 4 can on the other hand for example comprise one or several p-doped layers 4a, 4b, respectively, as well as one or several undoped barrier layers 4c adjacent to the active region 5. Both layers 3d and 4c may comprise the same or a very similar composition material with regards to the active layer 5. In the given example both comprise undoped InGaAIP material.

The optoelectronic device 1 further comprises inclined sidewalls starting from the first charge transportation layer up to the top layer 4a of the charge carrier layer 4. The area of the top sub-layer 4a is smaller than the other sub-layers and/or the first charge carrier transportation layer. In other words, the inclined surface with angle a to the normal N is smaller than 90°.

The inclined surfaces of the sidewalls of layer stack 2 are covered by a first regrowth layer 6 covering the side surfaces 2b and leaving at least portions of the top surface 2a exposed. The first regrowth layer, in the embodiment shown, comprises two undoped sub-layers. The material of undoped layers of the first regrowth layer 6 are chosen to provide a larger bandgap than the active region 5, but optionally also of the adjacent layers of the first and second charge transportation layer. The larger bandgap causes an electrical barrier preventing charge carriers injected into the active region from diffusing to the side wall and recombining in a non-radiative manner.

The material is undoped, again to prevent dopant diffusion into the active region. To this extent the first regrowth layer has been optimized in this regard both from a perspective of creating an electrical barrier and from a diffusion prevention perspective. In some other instances, the first regrowth layer comprises a small undoped first sub-layer directly adjacent to the surface of the side edges, but otherwise includes a plurality of sub-layers of a different doping type arranged in an alternating order. The selection of doping as well as its concentration is set to provide a npnp or pnpn barrier structure, when looking from the direction of one of the charge carrier transportation layers. The npnp or pnpn structure formed by the first regrowth layer in combination with some sub-layers of the charge carrier transportation layer and the second regrowth layer 7 (grown next) provides an additional barrier to prevent the generation of a parasitic pn-junction and avoid current leakage around the active region.

The top surface of the uppermost sub-layer 4a of the second charge carrier transportation layer 4 is on the same level as the edges of the undoped sub-layers of the first regrowth layer forming a substantially flat surface. The flat surface is now overgrown with a second regrowth layer 7. The regrowth layer extends also onto the surface of the first regrowth layer 6 on the inclined side walls. The second regrowth layer 7 also comprises one or more sub-layers with the outermost layer forming the contact layer of the optoelectronic device.

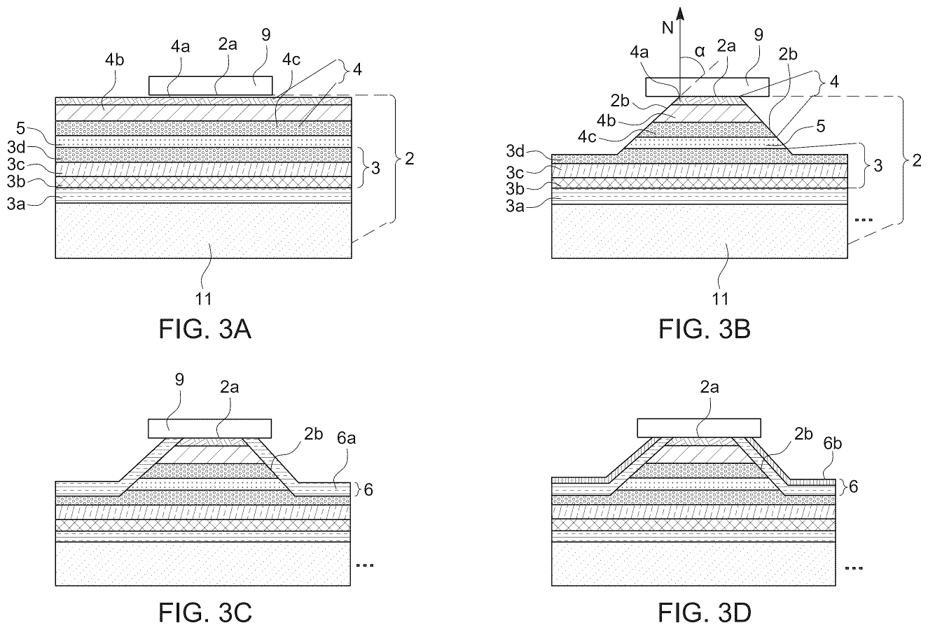

FIGS. 3A to 3D illustrate some steps of the processing process including the first regrowth step. In this regard and for the purpose of the following embodiment, the respective ternary and quaternary material compositions are presented in their respective general formulas. For example, an InₓAl₁₋ₓP layer is presented as InAlP layer ignoring the stoichiometric parameter x for simplicity. The same applies for Inₓ(Ga_{y}Al_{1-y})₁₋ₓP layer written as InGaAIP layer unless otherwise noted. The parameter x and y are chosen to select the overall desired bandgap and lattice constant, respectively. By selectively changing or varying the parameter y for example, one can change the bandgap of the quaternary semiconductor material keeping the Indium content constant.

FIG. 3A illustrates the formation and processing of the layer stack 2. A GaAs carrier wafer 11 is provided, which is prepared to facilitate the subsequent epitaxial growth process. This will include the processing and preparation of the surface of the GaAs carrier wafer 11 as well as the deposition of one or more buffer layer structure, not illustrated herein to provide a smooth and defect free surface. In a next step, the first charge carrier transportation layer 3 is deposited by applying several undoped and n-doped layers on top of each other and on the surface of the carrier wafer 11. In particular, an n-doped AlGaAs buffer layer 3a is deposited on the carrier, which may not be part of the final thin film device. A first an n-doped InGaAIP contact layer 3b of first charge carrier transportation layer 3 is deposited on top of the AlGaAs buffer layer 3a.

The doping concentration of layer 3b may vary to provide a good current injection into the subsequent layers as well as a sufficiently good current distribution along the overall area to improve the quantum efficiency. It is possible to adjust or vary doping concentration during the deposition of the n-doped layers. Likewise, one may adjust the above-mentioned parameter x and y for the quaternary material composition of layer 3b. Layer 3c deposited on top of layer 3b is an undoped InAlP barrier layer 3c. The doping concentration as well as the Ga content can be either smoothly reduced, but also changed abruptly. On top of layer 3c another undoped InGaAIP cladding layer 3d having a thickness of a few tens of nm is deposited.

In most instances, the buffer layer 3a can be removed in subsequent steps after re-bonding the wafer.

In a subsequent process step, active layer 5 is deposited on the cladding layer 3d of the first charge carrier transportation layer 3. The active layer 5 may comprise one or more undoped InGaAIP layers acting as quantum well and quantum barrier structures, respectively.

In particular, the aluminum content for the barrier layers is adjusted to a higher value than the respective quantum well layers. For example, the Al content can range between y=1 to y=0.3. The thickness of the respective barrier and quantum well sub-layers of active region 5 lies in the range of a few nm, and a plurality of alternating quantum well sub-layers and barrier sub-layers can be deposited.

An undoped cladding layer 4c of the same material as layer 3d is deposited on the surface of the last barrier sub-layer of active region 5. The undoped cladding layer 4c forms a portion of the second charge carrier transportation layer 4 comprising the before mentioned cladding layer, a p-doped InAlP barrier layer 4b as well as a further p-doped InGaAlP sub-layer 4a, respectively. +The top surface of the topmost sub-layer 4a of the second charge carrier transportation layer 4 forms the top surface of the layer stack 2 in accordance with the proposed principle.

FIG. 3B illustrates the next process step, in which a hard mask layer 9 is deposited on the top surface of the uppermost sub-layer 4a of the second charge carrier transportation layer 4. The material of hard mask layer 9 may comprise any material suitable for the subsequent etching process to protect portions of the respective layer stack 2 and to form island of layer stack material on the carrier substrate.

The material of hard mask 9 is then structured as to expose portions of the uppermost sub-layer 4a of the second charge carrier transportation layer 4. The surface 2a still covered by the structured mask material 9 will subsequently form the top surface of the structured layer stack as illustrated herein.

An etch process is performed in a subsequent step illustrated in FIG. 3B, selectively etching through various sub-layers and the active region 5 of the layer stack down to the cladding layer 3d of the first charge carrier transportation layer 3. This will expose in particular side edges and sidewalls of active region 5 and the respective barrier and quantum well layers therein. As illustrated, the sidewalls of the layer stack 2 are inclined due to the etching process with an under-cut below the structured mask layer 9. Accordingly, mask layer 9 extends beyond the top surface 2a of the outermost layer 4a of the second charge carrier transportation layer 4.

After cleaning and removing residuals from the inclined surface 2b of the layer stack 2, a first regrowth process is initiated depositing an undoped layer material on the sidewalls of the layer stack as well as on the remaining exposed portions of the cladding layer 3d.

This regrowth process is partially performed in a gas phase, such that an undoped material of regrowth sub-layer 6a is grown on the inclined sidewalls of the layer stack and on the surface of cladding layer 3d.

The undoped material regrown during the first regrowth process comprises a bandgap that is higher than the bandgap of the active region 5. As a result, an electrical barrier is formed preventing the charge carriers within the active region 5 from reaching the outer edges, that is the interface to the undoped regrowth layer 6a. A plurality of further sub-layers 6b can be provided on top of the thin undoped sub-layer 6a of the first regrowth layer to form an undoped stack or a npnp or a pnpn barrier structure. The plurality of sublayers 6a and 6b form the first regrowth layer 6 which also prevents current leakage between the second regrowth and the layer 3. The resulting structure with the first regrowth layer finished is illustrated in FIG. 3D.

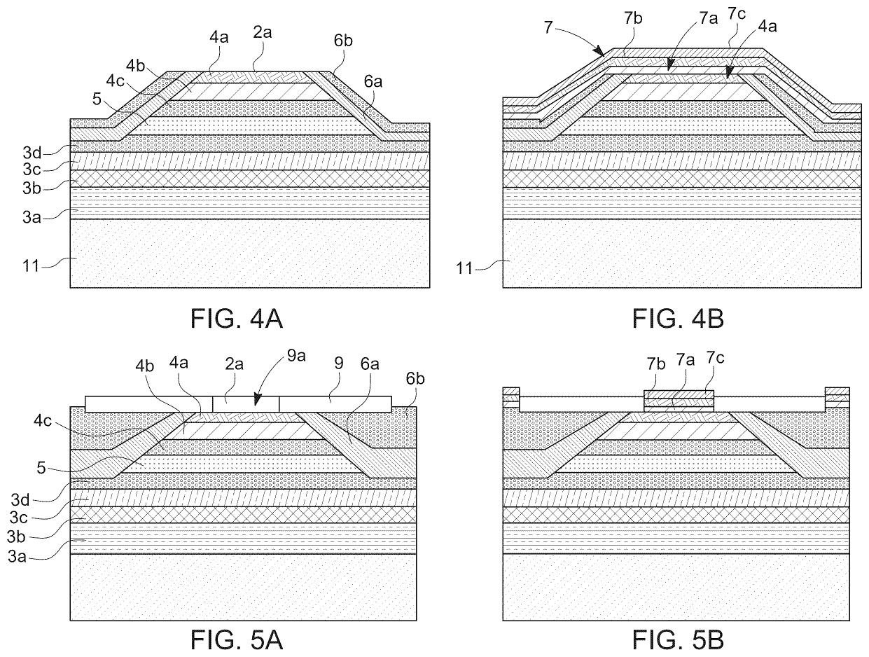

FIGS. 4A and 4B illustrate the next process steps in accordance with an embodiment of the proposed principle. In FIG. 4A, the mask layer previously arranged on the top surface 2a of the outermost top sub-layer 4a of charge carrier transportation layer 4 is removed, exposing the top surface 2a itself as well as the adjacent top surfaces of the first regrowth sub-layers 6a and 6b, respectively. If needed the surface can be cleaned.

Then, a subsequent second regrowth process is applied to the top surface. In particular, a plurality of sub-layers 7a, 7b and 7c are epitaxially regrown on the top surface 2a covering the top surface 2a as well as the adjacent first regrowth layer 6 completely. The second regrowth layer 7 comprises the three sub-layers 7a, 7b and 7c. The uppermost sub-layer of the second regrowth layer 7, namely sub-layer 7c is a highly p-doped contact layer, for example a p-doped GaP layer. In subsequent steps, not shown herein, the optoelectronic devices can be further processed and separated for example.

The different regrowth processes, namely the first regrowth process to cover the sidewalls 2b of the exposed active region 5 and the layer stack 2 as well as the second regrowth process to form a contact layer 7c provides the possibility to optimize both regrowth layers separately from each other.

In particular, the first regrowth layer may include a material composition that facilitates the radiative recombination not only in the center of the active region 5, but also close to its side edge. The undoped material also prevents an undesired dopant diffusion into the active region from the p-doped layers of the second regrowth process. The second regrowth process is optimized for a good carrier injection into the second charge carrier transportation layer 4. The undoped layer of the first regrowth process may prevent current leakage through a parasitic pn-junction with regards to the structure in conventional techniques. In addition, both regrowth processes may include additional doped sub-layers forming a pnpn or npnp structure (either as standalone or in combination with the doped sub-layers of the charge carrier transportation layer), which causes an electrical blocking barrier.

The material composition used for both regrowth layers can be fit together to the extent that their respective crystal lattices match avoiding the lattice mismatch and further defects in the interfaces of the respective regrowth layer or between the first regrowth layer and the active region.

The principle of generating two independent regrowth layers, each of them optimized for its specific purpose can be varied in accordance with the proposed principle using the mask etch layer 9 as a basis for further processing steps. FIGS. 5A and 5B illustrate another embodiment, which utilizes the mask layer 9 is a permanent installed layer for the optoelectronic device.

FIG. 5A shows the result after the first regrowth process is finished. The material deposition of the second sub layer 6b of the first regrowth layer 6 is continued until the space between the inclined surface and the mask layer is completely filled. The material therefore fills the space generated during the mesa etching process with the bottom surface of the mask layer being completely covered. As illustrated in the respective figure, material of the second sub layer 6b will partially also fill in the gaps between the structured mask layer 9.

In a subsequent step illustrated in FIG. 5A, the insulating material of mask layer 9 is then further structured to form a recess 9a in approximately the center exposing the top surface 2a of the uppermost second charge carrier transportation layer 4. The recess as shown is generally smaller than the overall top surface 2a, allowing even with a small misalignment of about 200 nm to expose the top surface and not the adjacent material of the first regrowth layer.

The recess is then filled up with several sublayers in a second regrowth process depositing material of a first sub-layer 7a on the top surface 2a of the second charge carrier transportation layer 4. Further sub-layers of the second regrowth process, namely layer 7b as well as contact layer 7c are deposited thereupon, whereas the top surface of the contact layer 7c can exceed the level of the surrounding top surface of mask layer 9. Compared to the previous implementation, this process may simplify the processing of an optoelectronic device by avoiding the need to remove the mask, while providing the contact layer 7c with the second regrowth process only in areas above the exposed top surface 2a of the second charge carrier transportation layer. In other words, and as shown in FIG. 5B, material of the mask layer is left on the top surface 2a, such that material of the second regrowth process layer 7 is deposited only on the top surface 2a but separated from the first regrowth layer by insulating material of the mask layer 9.

Consequently, further current leakage between the interfaces of the first and second regrowth layers, respectively, as well as between the first regrowth layer and the active region is thereby prevented. In addition, the processing of the first regrowth layer with its sub layers 6a and 6b may be simplified by providing an undoped material composition.

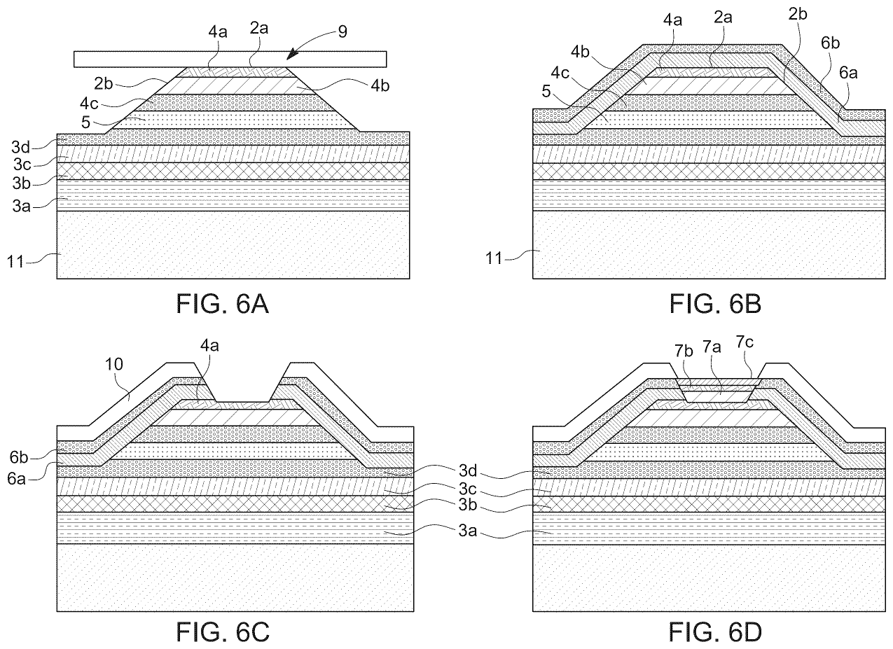

FIGS. 6A to 6D illustrate a further embodiment in accordance with the proposed principle. This embodiment deviates from the previous embodiments after the etching of the inclined surface 2b of layer stack 2 covered with the mask layer material. The material of mask layer 9 is removed in this embodiment and the first regrowth process is initiated afterwards.

Particularly sub-layer 6a with an undoped material of a higher bandgap is deposited on the exposed areas of the top surface and the etched sidewall portions. A second sub layer 6b covering completely the inclined sidewalls as well as the top surface is deposited on top of the first sub-layers 6a. The resulting structure after the first regrowth process is illustrated in FIG. 6B.

In a subsequent step shown in FIG. 6C and after depositing the first regrowth layer, an insulating mask layer 10 is deposited on the overall structure covering the first regrowth layer. The mask layer 10 is structured and a recess in mask layer 10 as well as the sub-layers of the first regrowth layer are formed, preferably centrally above the top surface 2a. The etching process will expose the top surface and, in some instances, etch a small portion into the top surface of the layer 4a of second charge carrier transportation layer 4. Similar to the previous steps, a second regrowth process is then initiated with a plurality of sub layers. The uppermost sub-layer of the second regrowth process is again a p-doped GaP layer forming the contact portion for the second charge carrier transportation layer.

The resulting structure of the presented embodiments therein can then be further processed, e.g. separated if needed and contacted from both sides using the p-doped contact layer 7c as well as the n-doped contact layer 3b on the other side.

Any optimization for the p-doped contact layer does not influence the electrical characteristics of the interface between the active region 5 and the first regrowth layer 6. The undoped material used in the first regrowth layer 6 or its npnp and pnpn structure, respectively will prevent a parasitic diode and current leakage. In addition, optimization of the first regrowth layer, particularly of the interface between the first regrowth layer and the active region will significantly improve the quantum efficiency for the active region and the optoelectronic device.

1.-20. (canceled)

21. An optoelectronic device comprising:
a layer stack having a first charge carrier transportation layer of a first doping type, a second charge carrier transportation layer of a second doping type, and an active region arranged between the first and second charge carrier transportation layers, wherein the layer stack comprises a top surface and side wall surfaces adjacent to the top surface, and wherein the side wall surfaces are inclined with respect to a normal of the top surface;
a first regrowth layer covering the side wall surfaces and leaving at least portions of the top surface exposed, wherein the first regrowth layer comprises a larger bandgap than at least the active region and is undoped or comprises a plurality of sub-layers of a different doping type arranged in an alternating order; and
a second regrowth layer arranged on exposed portions of the top surface thereby forming a p-doped contact layer to the second charge carrier transportation layer; and
a structured insulating material covering portions of the top surface and extending on surface portions of the first regrowth layer substantially on the same level as the top surface.

22. The optoelectronic device according to claim 21, wherein the first regrowth layer leaves the top surface exposed, and wherein the second regrowth layer extends on the top surface and optionally partially on exposed edges of the first regrowth layer.

23. The optoelectronic device according to claim 21, wherein the second regrowth layer extends on the first regrowth layer arranged on the side wall surfaces.

24. The optoelectronic device according to claim 21, wherein optionally the structured insulating material comprises a hard etch mask material; and/or the structured insulating material covers portions of the top surface adjacent to the first regrowth layer.

25. The optoelectronic device according to claim 21, further comprising a cavity that extends through the structured insulating material and the first regrowth layer exposing portions of the top surface, the cavity at least partially filled with the second regrowth layer.

26. The optoelectronic device according to claim 21, wherein each of the first and second charge carrier transportation layers comprises a cladding layer adjacent to the active region.

27. The optoelectronic device according to claim 21,
wherein the first regrowth layer comprises a material with a larger Al content than the active region of the layer stack, and/or
wherein the first regrowth layer comprises a bandgap that is larger than a bandgap of the first and/or second charge carrier transportation layers, and/or
wherein the first regrowth layer comprises a bandgap that is larger than a bandgap of the second regrowth layer.

28. The optoelectronic device according to claim 21, wherein the first regrowth layer is a III-V semiconductor layer, and/or wherein a content of aluminium in the first regrowth layer is greater than 25%.

29. The optoelectronic device according to claim 21,
wherein the second regrowth layer comprises p-doped InGaAIP, and/or
wherein the second regrowth layer comprises the same material as the second charge carrier transportation layers, and/or
wherein the second regrowth layer comprises a p doped InAlP layer adjacent to the second charge carrier transportation layer upon which one of a p-doped InGaAlP or a p-doped GaP contact layer is deposited.

30. A method for processing an optoelectronic device, the method comprising:
providing a layer stack having a first charge carrier transportation layer of a first doping type, a second charge carrier transportation layer of a second doping type, and an active region arranged between the first and second charge carrier transportation layers;
providing a structured mask on a top surface of the layer stack;
etching the layer stack such that the layer stack comprises side wall surfaces adjacent to the top surface thereby exposing edges of the active region;
regrowing a first regrowth layer at least on the side wall surfaces, wherein the first regrowth layer is undoped or comprises a plurality of sub-layers of a different doping type arranged in an alternating order;
exposing portions of the top surface of the layer stack;
regrowing a second regrowth layer on at least the exposed portions of the top surface, wherein the second regrowth layer comprises one or more sub-layers, an outermost sub-layer forming a doped contact layer, wherein regrowing the second regrowth layer comprises forming a recess in the structured mask to expose a portion of the top surface, and wherein optionally the recess is formed substantially centrally on the top surface distanced away from a material of the first regrowth layer; and
regrowing the second regrowth layer in the recess.

31. The method according to claim 30, wherein etching the layer stack comprises etching below a bottom surface of the structured mask to form an undercut.

32. The method according to claim 30, wherein regrowing the first regrowth layer comprises regrowing an undoped layer of a ternary or quaternary semiconductor material having an Al content that is larger than an Al content of the active region and/or the first and second charge carrier transportation layers.

33. The method according to claim 32, wherein regrowing the first regrowth layer comprises regrowing one or more doped layers on top of the undoped layers such that a pnpn or npnp structure is formed with the undoped layer in between two of the p and n layers and in which one of the p or n layers is part of the first and/or second charge carrier transportation layers.

34. The method according to claim 30, wherein regrowing the second regrowth layer comprises:
regrowing one or more layers that comprise the same material composition as layers of the second charge carrier transportation layer, and/or
regrowing an InAlP layer on at least exposed portions of the top surface and regrowing an InGaAP layer on the InAlP layer.

35. The method according to claim 30, wherein regrowing the first regrowth layer comprises:
removing a structured mask layer,
regrowing the first regrowth layer on sidewall surfaces and the top surface, and
providing the structured mask on top of the first regrowth layer.

36. The method according to claim 35, wherein regrowing the second regrowth layer comprises:
forming the recess through the structured mask and the material of the first regrowth layer to expose a portion of the top surface,
optionally insulating the sidewall surfaces of first regrowth layer portion in the recess, and
regrowing the second regrowth layer in the recess.

37. The method according to claim 30, wherein structuring the layer stack comprises etching the layer stack such that the structured mask protrudes over the side wall surfaces of the layer stack.

38. The method according to claim 30, wherein regrowing the second regrowth layer comprises a topmost layer forming a contact layer and optionally comprising p-doped GaP.
